(19) United States
(12) Patent Application Publication
(10) Pub. No.: US 2026/0271360 A1
(43) Pub. Date: Sep. 10, 2026

(54) SEMICONDUCTOR STRUCTURE HAVING LARGE SILICIDE WIDTH AND THICK CONTACT SPACER AND METHOD FOR MANUFACTURING THE SAME

(71) Applicant: TAIWAN SEMICONDUCTOR MANUFACTURING COMPANY, LTD., Hsinchu (TW)

(72) Inventors: Szu-Chien WU, Hsinchu (TW); Chun-Yuan CHEN, Hsinchu (TW); Huan-Chieh SU, Hsinchu (TW); Kuo-Cheng CHIANG, Hsinchu (TW); Chih-Hao WANG, Hsinchu (TW)

(73) Assignee: TAIWAN SEMICONDUCTOR MANUFACTURING COMPANY, LTD., Hsinchu (TW)

(21) Appl. No.: 19/072,458

(22) Filed: Mar. 6, 2025

(51) Int. Cl. H01L 21/285; H10D 30/00; H10D 30/01; H10D 64/01; H10D 64/62

(52) U.S. Cl. CPC H10D 64/0112; H10D 30/0193; H10D 30/503; H10D 64/01; H10D 64/62

(57) ABSTRACT

A method for manufacturing a semiconductor structure includes: forming a patterned structure having: a source/drain feature; a channel portion connected to the source/drain feature; a gate structure formed over the channel portion; and a patterned dielectric portion over the source/drain feature, the patterned dielectric portion having a trench that exposes the source/drain feature; forming a silicide layer over the exposed source/drain feature in the trench, the silicide layer having a curved profile and having an electrical conductivity higher than an electrical conductivity of the source/drain feature; forming a cap feature over the silicide layer in the trench; after forming the silicide layer and the cap feature, forming a contact spacer along the patterned dielectric portion in the trench, the cap feature being exposed from the contact spacer; and forming a conductive feature in the trench on the cap feature.

### BACKGROUND

As sizes of semiconductor devices shrinks, performance thereof could be greatly impacted by small variations in structural configuration of elements. Novel structures and manufacturing processes are proposed to enhance working performance in advanced semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 23 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

Source/drain feature(s) may refer to a source or a drain, individually or collectively dependent upon the context.

The present disclosure is directed to a semiconductor structure having large silicide width and thick contact spacer, and a method for manufacturing the same. The semiconductor structure has an active region, a channel portion, a gate structure, a source/drain feature, a silicide layer, a contact spacer, and a silicide contact. The active region extends lengthwise along a first direction. The channel portion is disposed on the active region. The gate structure is disposed over the channel portion, and extends lengthwise along a second direction different from the first direction. The source/drain feature is disposed on the active region, and is connected to the channel portion. In some embodiments, the channel portion includes a plurality of channel features, each of the channel features being connected to the gate structure, and being surrounded by the gate structure. The silicide layer is disposed on the source/drain feature. The source/drain contact is disposed on the silicide layer opposite to the source/drain feature. The source/drain contact has a base portion and a body portion. The base portion has a bottom surface that is connected to the silicide layer, and a top surface opposite to the silicide layer. The body portion is disposed on a central region of the base portion, and has a width smaller than a width of the base portion along both the first direction and the second direction. The contact spacer is disposed on and along a peripheral region of the base portion, and surrounds the body portion.

During a manufacturing process of the semiconductor structure, a patterned dielectric portion is formed over a source/drain feature. The patterned dielectric portion has a trench that exposes the source/drain feature. The silicide layer and a cap feature (i.e., the base portion of the source/drain contact) are first formed at a bottom of the trench over the exposed source/drain feature. The contact spacer is then formed along the patterned dielectric portion in the trench, and the cap feature is left exposed from the contact spacer. A conductive feature (i.e., the body portion of the source/drain contact) is then formed on the exposed cap feature. With such forming sequence, the silicide layer could be formed with a large width so as to have a small contact resistance between the source/drain contact and the source/drain feature. In addition, the contact spacer could be formed with a large thickness so as to have a small capacitance between the conductive feature and a gate electrode of the gate structure.

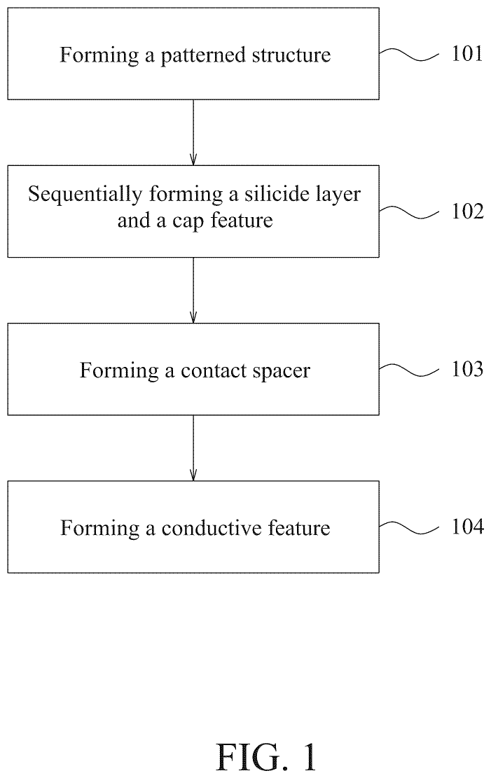

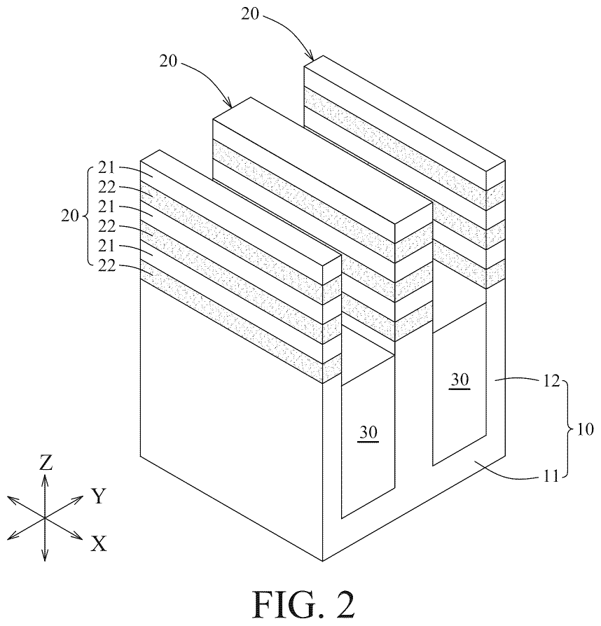

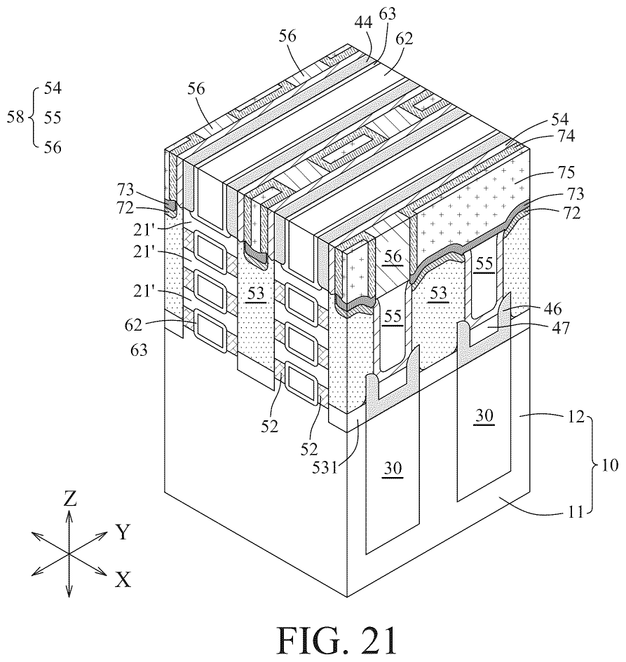

FIG. 1 is a flow diagram illustrating a method for manufacturing the semiconductor structure (for example, the semiconductor structure shown in FIGS. 21 to 23) in accordance with some embodiments. FIGS. 2 to 23 illustrate schematic views of intermediate stages of the method in accordance with some embodiments, and the steps illustrated in FIGS. 2 to 23 are also illustrated schematically in the flow diagram shown in FIG. 1. Some repeating structures are omitted in FIGS. 2 to 23 for the sake of brevity. Additional steps can be provided before, after or during the method, and some of the steps described herein may be replaced by other steps or be eliminated.

Referring to FIG. 2, fin stacks 20 and isolation features 30 are formed on a patterned substrate 10.

A material stack (not shown, which is to be formed into the fin stacks 20) is first formed on a starting substrate (not shown, which is to be formed into the patterned substrate 10).

The starting substrate may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The starting substrate may be formed with an n-type well (not shown) having an n-type conductivity and/or a p-type well (not shown) having a p-type conductivity. Each of the n-type well and the p-type well may be formed by introducing an n-type impurity or a p-type impurity into the starting substrate by an implantation processes. In some embodiments, the n-type impurity may include phosphorous (P, ³¹P), arsenic (As), antimony (Sb), or combinations thereof. In some embodiments, the p-type impurities may include boron or boron compounds (for example, B, ¹¹B, BF₂), aluminum (Al), indium (In), gallium (Ga), or combinations thereof. In some embodiments, the starting substrate may be a bulk silicon substrate, a silicon-on-insulator (SOI) substrate, or a germanium-on-insulator (GOI) substrate. In some embodiments, the starting substrate may be made of silicon. Other suitable materials for forming the starting substrate are within the contemplated scope of the present disclosure.

The material stack includes first material layers (not shown) and second material layers (not shown) that are alternatively stacked on each other over the starting substrate and that may be formed using any suitable deposition processes, such as physical vapor deposition (PVD), chemical vapor deposition (CVD), atomic layer deposition (ALD), other suitable processes, or combinations thereof, but are not limited thereto. In the following description, a deposition process, unless otherwise stated or defined in this disclosure, may be performed in a way similar to the above-mentioned ones. In some embodiments, the first material layers are made of a first semiconductor material, and the second material layers are made of a second semiconductor material different from the first semiconductor material. Possible materials for the first and second semiconductor materials are similar to those for the starting substrate, and thus details thereof are omitted for the sake of brevity. In some embodiments, the material stack includes three of the first material layers, and three of the second material layers. In some other embodiments, a number of the first material layers or the second material layers may be greater than three or less than three. For instance, the number of each of the first material layer and the second material layers may range from approximately 2 to 6, but is not limited thereto. In certain embodiments, the first material layers include or are made of silicon, while the second nanosheet layers include or are made of silicon germanium. Other suitable processes, materials, numbers and/or dimensions for each of the first and second material layers are within the contemplated scope of the present disclosure.

In some embodiments, a patterning process is performed to pattern the starting substrate into the patterned substrate 10 which includes a base 11 and protrusions 12 (which may be referred to as protrusions on the base 11), and to pattern the material stack into the fin stacks 20 which are respectively disposed on the protrusions 12.

The patterning process may include a photolithography process followed by an etching process. The photolithography process may include: forming a photoresist layer over a structure to be patterned by, e.g., spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In the following description, a patterning process, unless otherwise stated or defined in this disclosure, may be performed in a way similar to the above-mentioned ones. In some embodiments, before the patterning process, a masking layer (not shown, may be made of silicon oxide, silicon nitride, other suitable materials, or combinations thereof) is formed on the material stack using a suitable deposition process; and in the etching process, the masking layer is patterned by the patterned photoresist layer into masking regions (not shown), and then the starting substrate and the material stack are patterned using the masking regions as an etching mask.

The protrusions 12 are disposed on the base 11, each extends lengthwise along an X direction, and are spaced apart from each other in a Y direction different from (e.g., perpendicular to) the X direction. Each of the protrusions 12 may be referred to as an active region. The fin stacks 20 are respectively disposed on the protrusions 12 opposite to the base 11 in the Z direction different from (e.g., perpendicular to) the X direction and the Y direction, and thus are spaced apart from each other in the Y direction. The first material layers are patterned to form channel layers 21 of the fin stacks 20; and the second material layers are patterned to form sacrificial layers 22 of the fin stacks 20. Other suitable processes for forming the channel layers 21 and the sacrificial layers 22 are within the contemplated scope of the present disclosure.

In some embodiments, after forming the patterned substrate 10 and the fin stacks 20, the isolation features 30 are formed. Each of the isolation features 30 is formed on the base 11 between two adjacent ones of the protrusions 12, and extends lengthwise along the X direction. In some embodiments, the isolation features 30 are each a shallow isolation features (STI), a deep trench isolation (DTI), or other suitable structures. The isolation features 30 may be formed by: depositing an isolation material for forming the isolation features 30 using any suitable deposition processes such that the isolation material fills spaces among the fin stacks 20; performing a planarization process (e.g., chemical mechanical polishing (CMP)) to obtain a planarized surface, through which the masking regions (not shown)remaining respectively on the fin stacks 20 are exposed; and etching back the isolation material using any suitable etching processes, such as dry etching, wet etching, anisotropic etching, or combinations thereof. In the following description, an etching process, unless otherwise stated or defined in this disclosure, may be performed in a way similar to the above-mentioned ones. In some embodiments, after forming the isolation features 30, the masking regions are removed. In some embodiments, upper surfaces of the isolation features 30 may be at a level lower than a level of upper surfaces of the protrusions 12. In some embodiments, the isolation features 30 include or are made of a dielectric material, such as an oxide-based material (e.g., silicon oxide, silicon oxynitride, silicon oxide formed from tetraethoxysilane (TEOS), or other suitable materials), silicon nitride, other low-k dielectric materials, or combinations thereof. Other suitable processes, materials and/or configurations of the isolation features 30 are within the contemplated scope of the present disclosure.

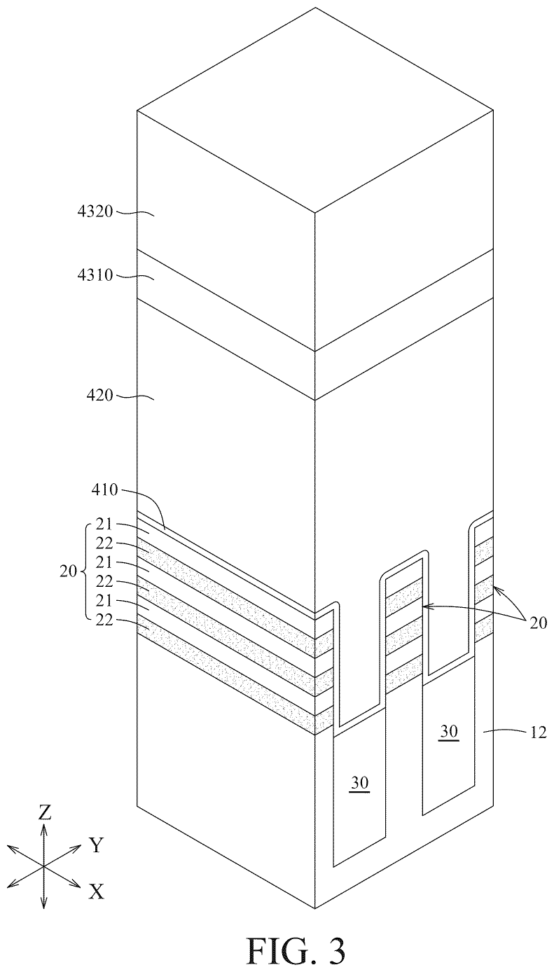

Referring to FIG. 3, a stack including a first dummy layer 410, a second dummy layer 420, a first mask layer 4310, and a second mask layer 4320 are formed.

In some embodiments, the first dummy layer 410 includes or is made of silicon oxide, silicon nitride, silicon oxynitride, high dielectric constant (k) materials, or combinations thereof. In some embodiments, the second dummy layer 420 includes or is made of polycrystalline silicon, single crystalline silicon, amorphous silicon, or combinations thereof. In some embodiments, the first mask layer 4310 and the second mask layer 4320 include or are made of different materials. Each of the first mask layer 4310 and the second mask layer 4320 may include or may be made of a dielectric material, such as silicon nitride, silicon oxide, silicon oxynitride, or combinations thereof.

In some embodiments, the stack may be formed by: sequentially depositing the first dummy layer 410 and a second dummy material layer (not shown); performing a planarization process (e.g., CMP) to obtain a planarized second dummy layer that serves as the second dummy layer 420; and sequentially forming the first mask layer 4310 and the second mask layer 4320 over the dummy stack using any suitable deposition processes. Other suitable materials and/or processes for forming the stack are within the contemplated scope of the present disclosure.

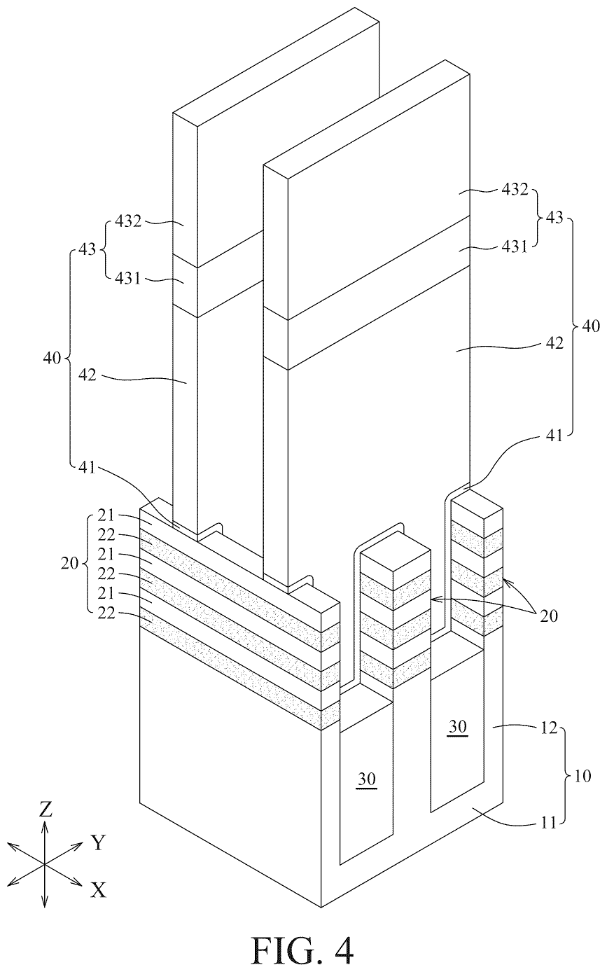

Referring to FIG. 4, the stack described in FIG. 3 is patterned into dummy structures 40.

In some embodiments, the first mask layer 4310 (see FIG. 3) is patterned into first hard masks 431, and the second mask layer 4320 (see FIG. 3) is patterned into second hard masks 432, using any suitable patterning processes. Each one of the first hard masks 431 and a corresponding one of the second hard masks 432 cooperatively serve as a hard mask unit 43. As shown in FIG. 4, two hard mask units 43 are obtained. Afterwards, the first dummy layer 410 (see FIG. 3) is patterned into dummy dielectrics 41, and the second dummy layer 420 (see FIG. 3) is patterned into dummy gates 42, using any suitable patterning processes, through the hard mask units 43. Other suitable processes for forming the gate structures 40 are within the contemplated scope of the present disclosure. In some embodiments, each of the hard mask units 43 may be a single layer structure by having only the first hard mask 431 or the second hard mask 432 (i.e., only the first mask layer 4310 or the second mask layer 4320 is formed in the stack as described with reference to FIG. 3).

Each one of the dummy dielectrics 41, a corresponding one of the dummy gates 42, and a corresponding one of the hard mask units 43, cooperatively serve as one of the dummy structures 40. Each of the dummy structures 40 extends lengthwise along the Y direction. Each of the dummy structures 40 is formed over, and partially exposes the fin stacks 20 and the isolation elements 30.

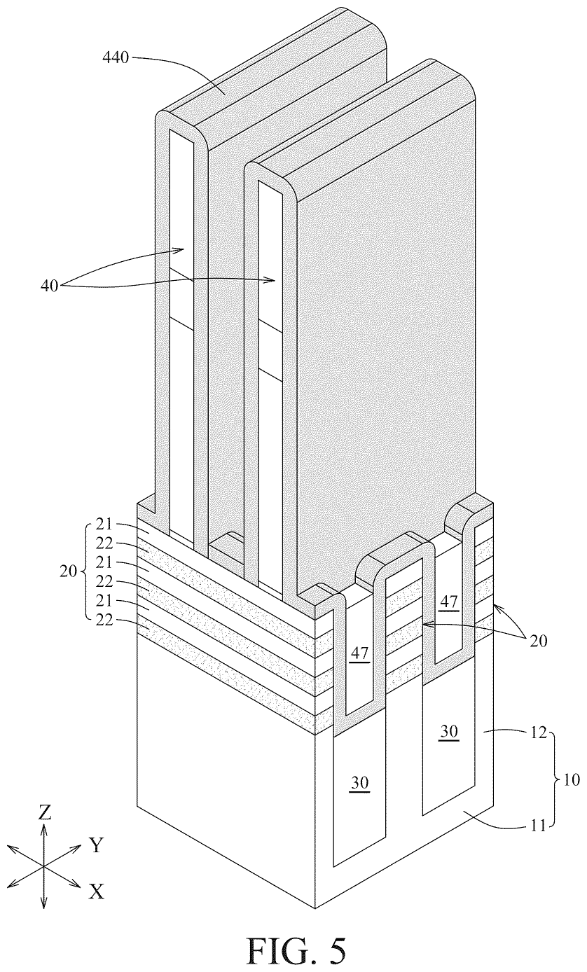

Referring to FIG. 5, a spacer material layer 440 and dielectric features 47 are sequentially formed.

The spacer material layer 440 is first conformally formed over the dummy structures 40, the fin stacks 20 and the isolation features 30 using any suitable deposition processes. The spacer material layer 440 may include or may be made of silicon oxide, silicon nitride, carbon-doped silicon oxide (which may be referred to as silicon oxycarbide), nitride-doped silicon oxide (which may be referred to as silicon oxynitride), silicon oxycarbon nitride, silicon carbon nitride, a porous oxide material, other suitable low dielectric constant (low-k) materials, or combinations thereof. Other suitable materials for the spacer material layer 440 are within the contemplated scope of the present disclosure.

Afterwards, the dielectric features 47 are formed on the spacer material layer 440. The dielectric features 47 may be formed by any suitable deposition processes followed by an etch-back process (e.g., dry etching, wet etching, any suitable etching processes or combinations thereof). Each of the dielectric features 47 is located on a corresponding one of the isolation features 30 between two corresponding adjacent ones of the fin stacks 20 in the Y direction. The dielectric features 47 may include or be made of a dielectric material, such as silicon oxide, but is not limited thereto. In some embodiments, the dielectric features 47 may include a material different from that of the spacer material layer 440. Other suitable materials for the dielectric features 47 are within the contemplated scope of the present disclosure.

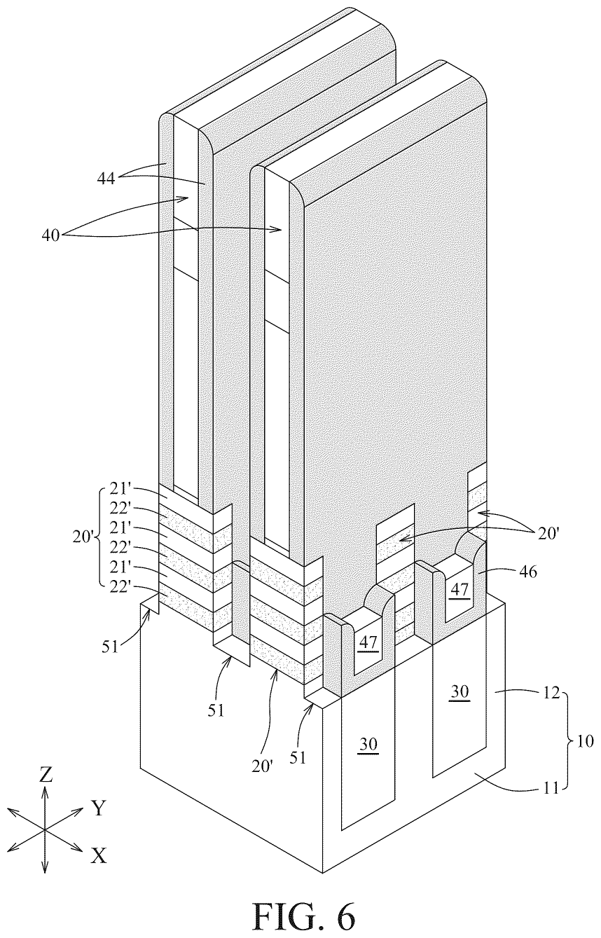

Referring to FIG. 6, the spacer material layer 440 (see FIG. 5) is patterned into gate spacers 44 and fin sidewalls 46. Each of the fin stacks 20 is patterned into stack portions 20′ that are spaced apart from each other by source/drain recesses 51. The dummy structures 40, the dielectric features 47, the protrusions 12 shown in FIG. 5 are also recessed when patterning the spacer material layer 440 and the fin stacks 20. In some embodiments, each of the protrusions 12 also has recessed portions. Any suitable patterning processes and/or etching processes may be employed.

Each of the stack portions 20′ is covered by a corresponding one of the dummy structures 40 and two corresponding ones of the gate spacers 44 (that sandwich the corresponding dummy structure 40 in the X direction, and that extend over the isolation features 30). Each of the stack portions 20′ has channel features 21′ that are formed from the channel layers 21 (see FIG. 5), and sacrificial features 22′ that are formed from the sacrificial layers 22. The channel features 21′ of each of the stack portions 20′ cooperatively serve as a channel portion. A lower portion of each of the source/drain recesses 51 is bordered by two corresponding ones of the fin sidewalls 46 in the Y direction. A bottom portion of each of the source/drain recesses 51, located beneath the lower portion, is bordered by one of the recessed portions of a corresponding one of the protrusions 12.

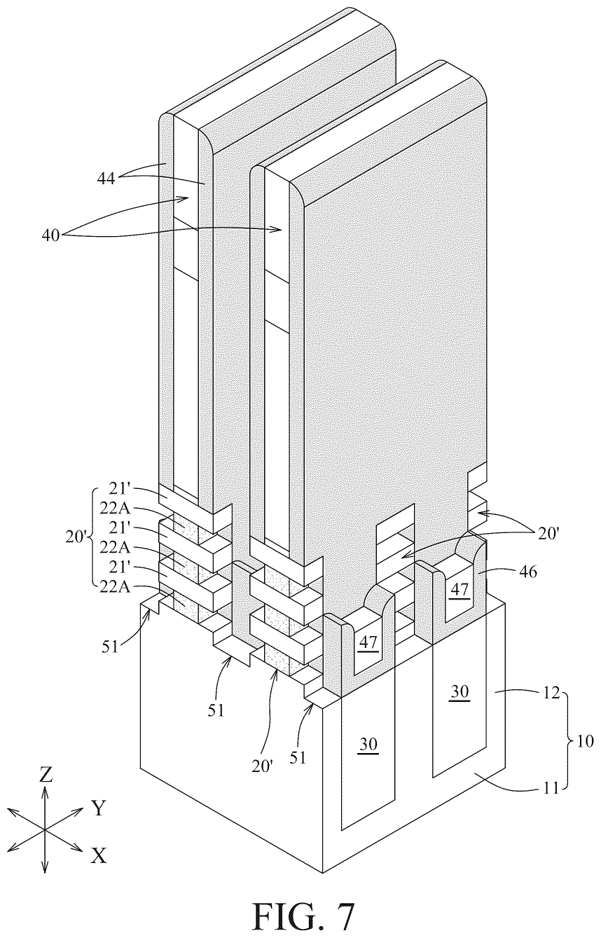

Referring to FIG. 7, end regions of each of the sacrificial features 22′ (see FIG. 6) that are opposite to each other in the X direction are removed to form recesses using any suitable patterning and/or etching processes. Hereinafter, the sacrificial features are denoted by the numeral 22A.

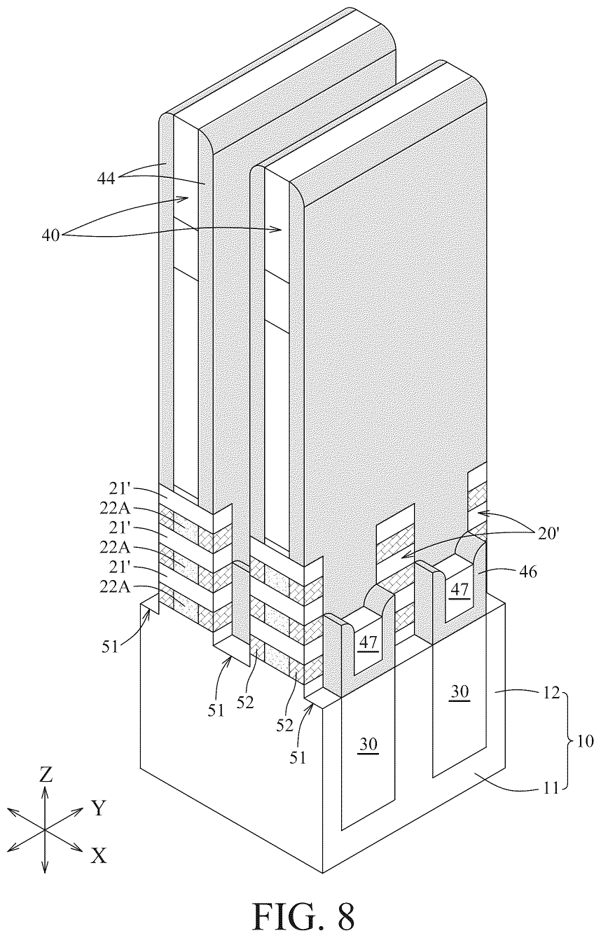

Referring to FIG. 8, inner spacers 52 are formed in the recesses described with reference to FIG. 7.

In some embodiments, the inner spacers 52 may be formed by: depositing an inner spacer material (not shown) to fill the recesses using any suitable deposition processes; and removing an excess amount of the inner spacer material using any suitable etching processes, thereby forming the inner spacer material into the inner spacers 52. In some embodiments, the inner spacers 52 (the inner spacer material) include or are made of silicon oxide, silicon oxycarbide, silicon nitride, silicon oxynitride, silicon carbide, silicon oxycarbonitride, air gaps, other suitable low-k dielectric materials, or combinations thereof. Other suitable materials and/or processes for forming the inner spacers 52 are within the contemplated scope of the present disclosure.

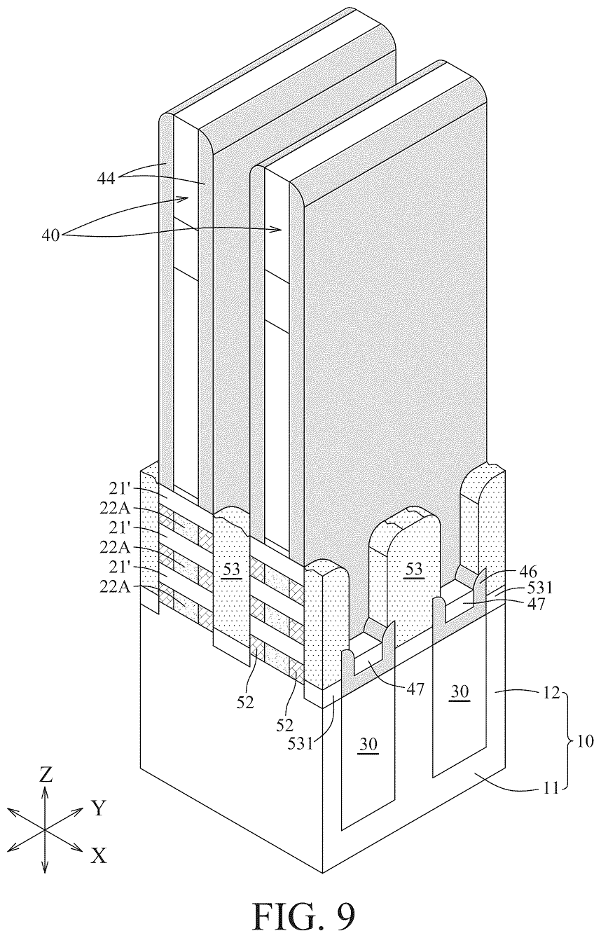

Referring to FIG. 9, interposing layers 531 and source/drain features 53 are formed in the source/drain recesses 51.

The interposing layers 531 are first formed at the bottom portions of the source/drain recesses 51, respectively. In one embodiment, the interposing layers 531 may include or be made of a dielectric material, such as silicon oxide, silicon nitride, silicon carbide, silicon oxynitride, silicon oxycarbide, silicon carbon nitride, or the likes, or combinations thereof, but are not limited thereto. The interposing layers 531 may be formed by any suitable deposition process. In some embodiments, the interposing layers 531 may include an undoped or unintendedly doped Si, SiGe. In some embodiments, the interposing layers 531 include multiple layers, for example, one of the layers is an undoped (or unintendedly doped) Si, SiGe, while another one of the layers includes dielectric material described above. Other suitable materials and/or processes for forming the interposing layers 531 are within the contemplated scope of the present disclosure.

Afterwards, the source/drain features 53 are respectively formed in the source/drain recesses 51 and on the interposing layers 531. The source/drain features 53 are connected to, and are located adjacent to corresponding ones of the channel features 21′ in the X direction. In certain embodiments, each of the source/drain features 53 extend over the two corresponding fin sidewalls 46, and portions of each of the source/drain features 53 overhangs adjacent ones of the isolation features 30. In some embodiments, each of the source/drain features 53 has a thickness in the Z direction and a width in the Y direction, the thickness of each of the source/drain features 53 is different from the width, and the width of each of the source/drain features 53 is different from the thickness.

In some embodiments, the source/drain features 53 include or are made of single crystalline silicon, single crystalline silicon germanium alloy, single crystalline silicon carbon alloy, single crystalline silicon carbon germanium alloy, polycrystalline silicon, polycrystalline silicon germanium, polycrystalline silicon carbon alloy, polycrystalline silicon carbon germanium alloy, or other suitable materials. The source/drain features 53 may each be doped with n-type dopant(s) or p-type dopant(s). Examples for the n-type dopants and the p-type dopants are respectively similar to the n-type impurities and p-type impurities described above, and thus details thereof are omitted for the sake of brevity. In some embodiments, an epitaxy growth process (such as molecular-beam epitaxy (MBE), selective area epitaxy (SAE), etc.) or other suitable deposition techniques may be adopted for forming the source/drain features 53. In some embodiments, the source/drain features 53 may include single epitaxial layer or multiple epitaxy layers having different materials and/or different dopant concentrations. In some embodiments, the source/drain features 53 includes at least two epitaxy layers containing same semiconductor materials with different dopant concentrations. Other suitable materials and/or processes for forming the interposing layers 531 and/or the source/drain features 53 are within the contemplated scope of the present disclosure.

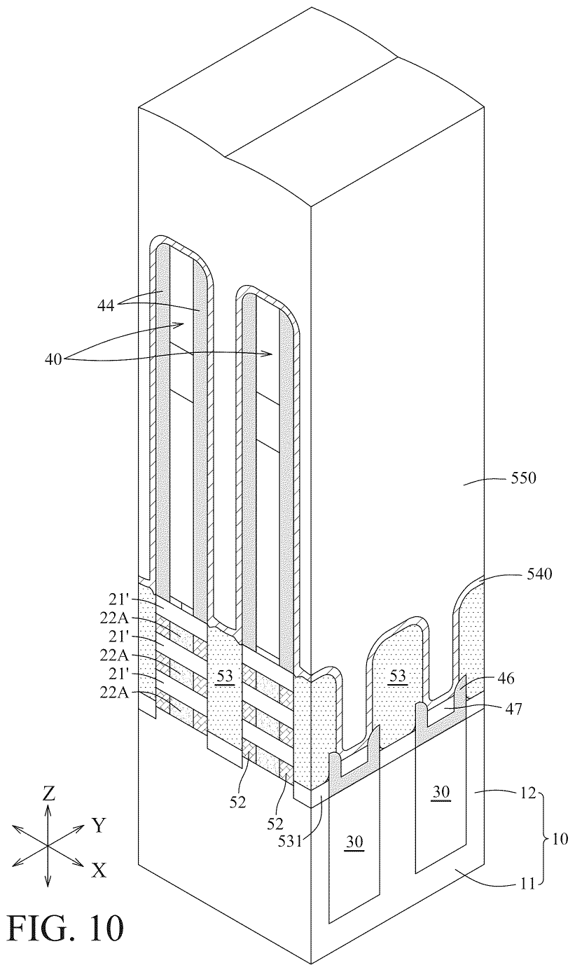

Referring to FIG. 10, a contact etch stop material layer 540 and an interlayer dielectric material layer 550 are sequentially formed over the structure shown in FIG. 9 using any suitable deposition processes.

Each of the contact etch stop material layer 540 and the interlayer dielectric material layer 550 may include or be made of a dielectric material such as silicon oxide, silicon nitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, or combinations thereof. The contact etch stop material layer 540 and the interlayer dielectric material layer 550 are made of different dielectric materials. Other suitable materials and/or processes for forming the contact etch stop material layer 540 and the interlayer dielectric material layer 550 are within the contemplated scope of the present disclosure.

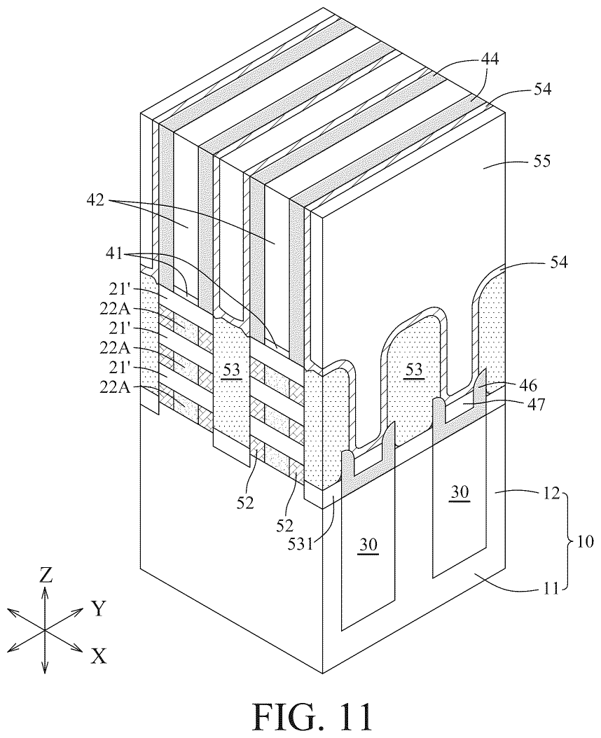

Referring to FIG. 11, a planarization process (e.g., CMP, but is not limited thereto) is performed to remove an excess amount of each of the contact etch stop material layer 540 and the interlayer dielectric material layer 550 described with reference to FIG. 10. The contact etch stop material layer 540 is formed into contact etch stop layers (CESLs) 54, and the interlayer dielectric material layer 550 is formed into interlayer dielectric layers (ILDs) 55. In some embodiments, the hard mask units 43 of the dummy structures 40 (see FIG. 10) are also removed in the planarization process.

After the planarization process, the dummy gates 42 are exposed. Each of the source/drain features 53 is located beneath one of the CESLs 54 and a corresponding one of the ILDs 55. Although an interface between each of the isolation features 30 and a corresponding one of the fin sidewalls 46 is a planar in FIG. 11, in some embodiments, the interface is non-planer. In addition, the isolation features 30 are located below the CESLs 54 and the ILDs 55.

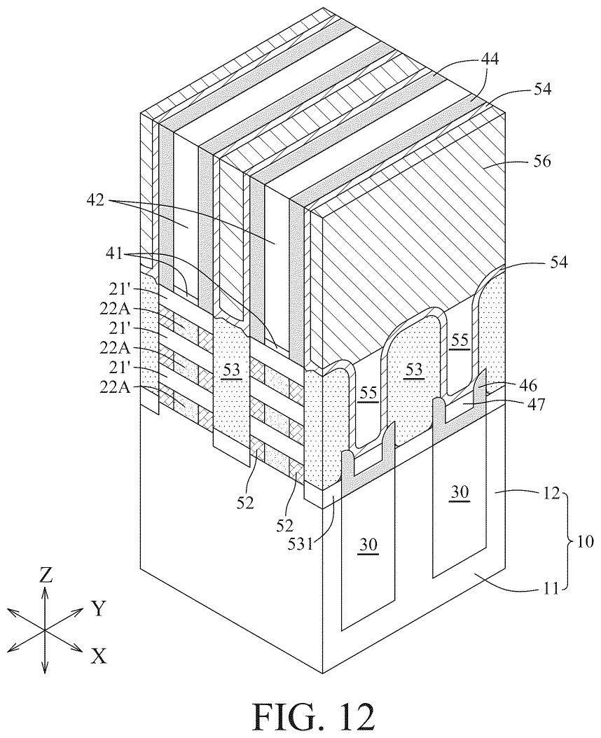

Referring to FIG. 12, the ILDs 55 are recessed, and dielectric masks 56 are formed.

In some embodiments, upper portions of the ILDs 55 that are located above the source/drain features 53 are removed using any suitable etching processes, leaving lower portions of the ILDs 55 remain among the source/drain features 53.

The dielectric masks 56 may be formed using any suitable deposition processes. In some embodiments, the dielectric masks 56 include or are made of a dielectric material, such as silicon oxide, silicon nitride, silicon oxynitride, high dielectric constant (k) materials, or combinations thereof. The dielectric masks 56 are made of a material different from that of the ILDs 55. Other suitable materials and/or processes for forming the hard mask layers 56 are within the contemplated scope of the present disclosure.

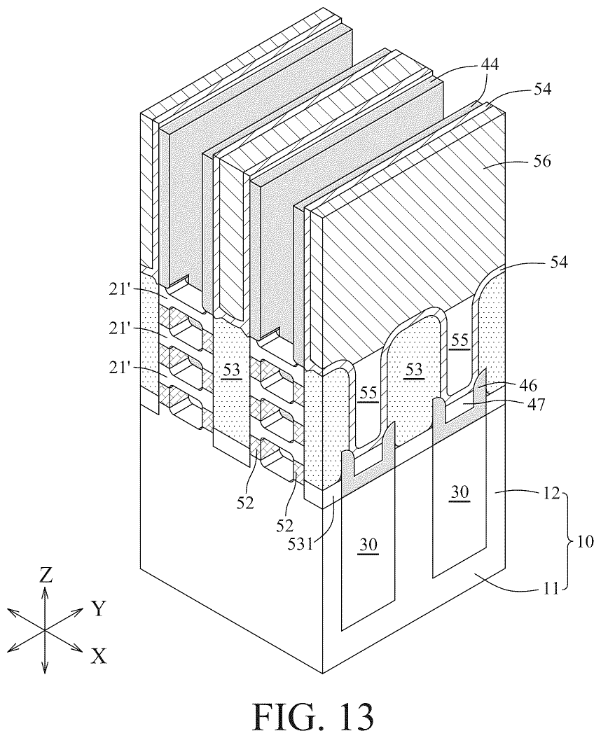

Referring to FIG. 13, the dummy dielectrics 41, the dummy gates 42, and the sacrificial features 22A are removed using any suitable etching processes. Other suitable processes for removing the dummy dielectric 41, the dummy gate 42 and the sacrificial features 22′ are within the contemplated scope of the present disclosure.

In addition, in some embodiments, the channel features 21′ are each recessed in the Z direction using any suitable etching processes.

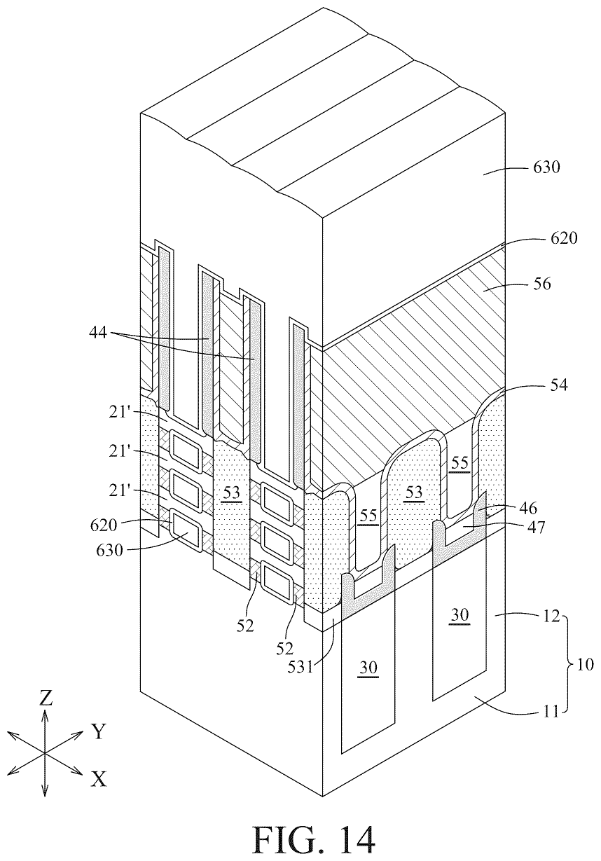

Referring to FIG. 14, a gate dielectric material layer 620 and a gate electrode material layer 630 are formed using any suitable deposition processes.

The gate dielectric material layer 620 is first conformally formed over the structure shown in FIG. 13. In some embodiments, the gate dielectric material layer 620 includes or is made of a high dielectric constant material, but is not limited thereto. The high dielectric constant material may be a dielectric material with wide band gap and good thermal stability. Examples of the high dielectric constant material are a hafnium-based dielectric material (e.g. hafnium oxide), zirconium oxide, titanium oxide, yttrium oxide, magnesium oxide, calcium oxide, zirconium silicate, aluminum oxide, scandium oxide, or other suitable materials. Other suitable materials and/or processes for forming the gate dielectric material layer 620 are within the contemplated scope of the present disclosure.

Afterwards, the gate electrode material layer 630 is formed to fill up spaces in the structure. The gate electrode material layer 630 may include or is made of a conductive material, such as a metal, a metal-containing nitride, a metal-containing silicide, a metal-containing carbide, or the like, but are not limited thereto. Other suitable materials and/or processes for forming the gate dielectric material layer 620 and/or the gate electrode material layer 630 are within the contemplated scope of the present disclosure.

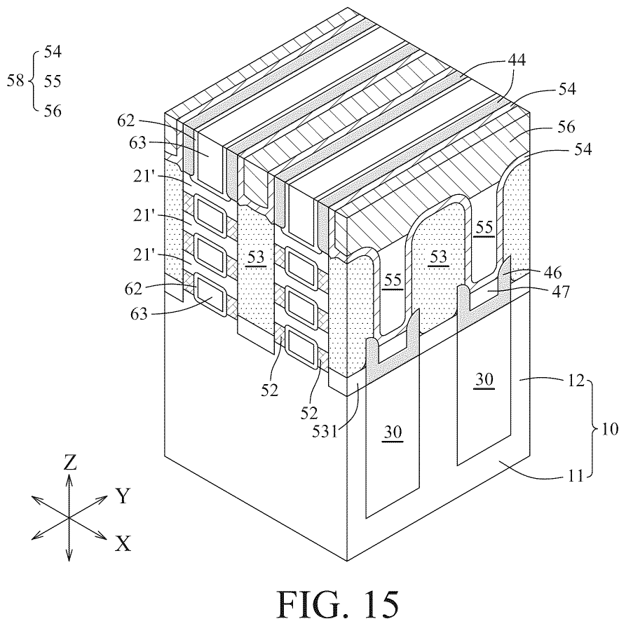

Referring to FIG. 15, a planarization process (e.g., CMP or other suitable processes) is performed to remove an excess amount of each of the gate electrode material layer 630 (see FIG. 14), the gate dielectric material layer 620, the gate spacers 44, the CESLs 54, and the dielectric masks 56.

After the planarization process, the gate electrode material layer 630 is formed into gate electrodes 63, and the gate dielectric material layer 620 is formed into gate dielectrics 62. Each of the gate electrodes 63 and a corresponding one of the gate dielectrics 62 cooperatively serve as a gate structure that is disposed over the channel portion and that extends lengthwise along the Y direction. Although not shown in the figures, the topmost surface of each of the isolation features 30 has a portion that intermixes at an interface between the gate structure and each of the isolation features 30. Although the topmost surface of each of the isolation features 30 is a planar surface shown in FIG. 15, in some embodiments, the topmost surface is non-planar. Although the isolation features 30 have the same height in FIG. 15, in some embodiments, the isolation features 30 may have different heights.

In addition, after the planarization process, a plurality of dielectric portions 58 are formed. Each of the dielectric portions 58 includes one of the dielectric masks 56, a corresponding one of the CESLs 54, and a corresponding one of the recessed ILDs 55. That is, each of the source/drain features 53 is covered by a corresponding one of the dielectric portions 58.

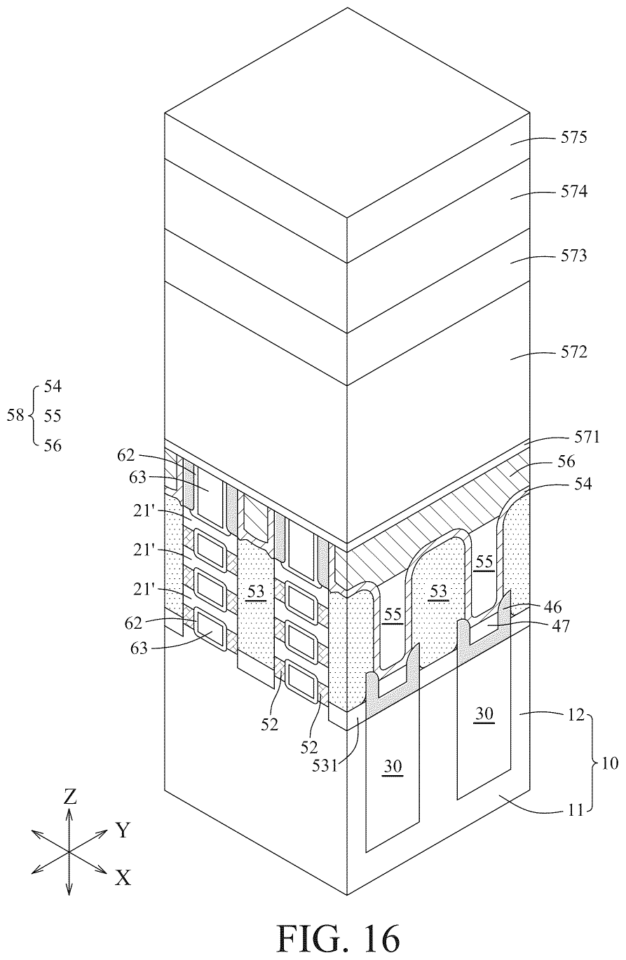

Referring to FIG. 16, a hard mask material stack is formed.

In some embodiments, the hard mask material stack includes a first mask layer 571, a second mask layer 572, a third mask layer 573, a fourth mask layer 574, and a fifth mask layer 575 that are sequentially formed over the structure shown in FIG. 15.

In some embodiments, each of the first mask layer 571, the second mask layer 572, and the fourth mask layer 574 includes or is made of a dielectric material. The first mask layer 571 is made of a material different from that of the second mask layer 572. In some embodiments, the third mask layer 573 may include or is made of a metallic material, such as a metal, a metal alloy, or a metal carbide, or other suitable materials, or combinations thereof. In some embodiments, the fifth mask layer 575 may include or is made of a silicon-based material, such as silicon, poly silicon, or other suitable materials, or combinations thereof. Each of the first, second, third, fourth and fifth mask layers 571, 572, 573, 574, 575 may be formed using any suitable deposition processes. Other suitable materials and/or configurations and/or processes for forming the hard mask material stack are within the contemplated scope of the present disclosure.

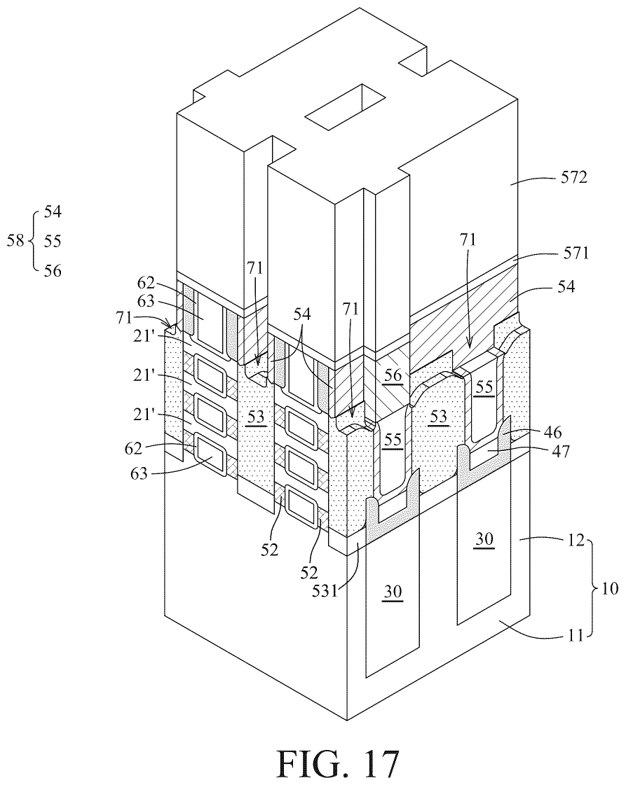

Referring to FIG. 17, the hard mask material stack as described with reference to FIG. 16 is first patterned, and then the dielectric portions 58 are patterned to expose the source/drain features 53 underneath.

The hard mask material stack may be patterned using any suitable patterning processes and/or etching processes. After the patterning process, the patterned third, fourth and fifth mask layers 573, 574, 575 are removed, while the patterned first and second mask layers 571, 572 remain.

The dielectric portions 58 are patterned through the patterned hard mask material stack, so as to form patterned dielectric portions (also denoted by 58) and trenches 71 within the patterned dielectric portions 58. Each of the trenches 71 is bordered by the CESL 54 and/or the dielectric mask 56 of a corresponding one of the dielectric portions 58 at sidewalls; and corresponding one(s) of the source/drain features 53 at bottom. Each of the trenches 71 may expose top surface(s) of one or more source/drain features 53. In the trench 71 that exposes multiple source/drain features 53, the recessed ILD 55 of the corresponding dielectric portion 58 may also be exposed.

After the patterning processes to form the patterned dielectric portions 58, a patterned structure is obtained. Step 101 in the flow diagram shown in FIG. 1 is exemplified by the structures shown in FIGS. 2 to 17.

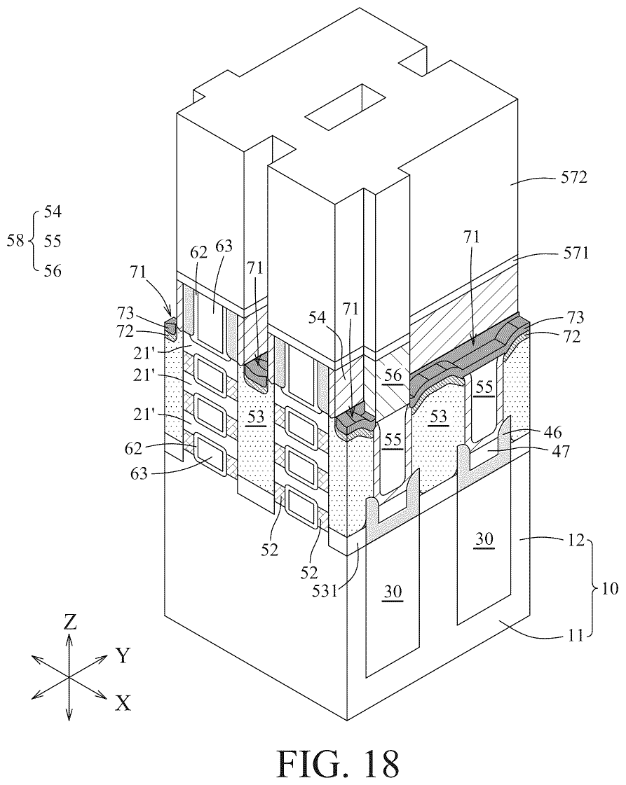

Referring to FIG. 18, silicide layers 72 and cap features 73 are sequentially formed at bottoms of the trenches 71 over the exposed source/drain features 53.

In some embodiments, first metallic material layers (not shown, for forming the silicide layers 72) are formed along sidewalls and bottoms of the trenches 71 on the source/drain features 53 using any suitable deposition processes. The first metallic material layers may include or may be made of titanium (Ti), nickel (Ni), zirconium (Zr), molybdenum (Mo), ruthenium (Ru), scandium (Sc), platinum (Pt), palladium (Pd), cobalt (Co), erbium (Er), hafnium (Hf), other suitable metal materials, or combinations thereof. Silicon atoms within the source/drain features 53 are then allowed to diffuse into parts of the first metallic material layers that are exposed to the source/drain features 53, and to react with metals in the first metallic material layers to form the silicide layers 72. The unreacted parts of the first metallic material layers are then removed using any suitable etching process. Other suitable materials and/or processes for forming the silicide layers 72 are within the contemplated scope of the present disclosure.

In certain embodiments, the silicide layers 72 are formed to have a curved profile. In some embodiments, the silicide layers 72 have an electrical conductivity higher than an electrical conductivity of the source/drain features 53.

Afterwards, the cap features 73 are formed. In some embodiments, the cap features 73 are formed as follows. A second metallic material layer (not shown, for forming the cap features 73) is formed over the structure after forming the silicide layers 72 to cover the sidewalls and the bottoms of the trenches 71 using any suitable deposition processes. Then, a blocking material is formed to fill the trenches 71 using any suitable deposition processes. The blocking material may be a bottom anti-reflective coating material, for example, a porous polymer made from styrene monomers and epoxy crosslinkers or other suitable materials. Next, the blocking material is etched back and formed into mask layers which respectively cover the bottoms of the trenches 71, and thus the silicide layers 72 are well-protected by the mask layers. As such, excess portions of the second metallic material layer are exposed from the mask layers. Thereafter, another etching back process is performed to remove the excess portions of the second metallic material layer, thereby obtaining the cap features 73. The mask layers are then removed using any suitable etching processes or ashing processes. The cap features 73 are formed over to cover the silicide layers 72. In the trench 71 that exposes multiple source/drain features 53 shown in FIG. 17, the cap feature 73 in such trench 71 may also cover the corresponding recessed ILD 55. The second metallic material layer may include or be made of a conductive material, such as tungsten (W), titanium (Ti), ruthenium (Ru), molybdenum (Mo), copper (Cu), cobalt (Co), aluminum (Al), palladium (Pd), nickel (Ni), platinum (Pt), a low resistivity metal constituent, or the like, or combinations thereof, but are not limited thereto. Other suitable materials and/or processes for forming the cap features 73 are within the contemplated scope of the present disclosure.

As such, each of the source/drain features 53 is covered by a corresponding one of the silicide layers 72 and a corresponding one of the cap features 73. In addition, the cap features 73 are then exposed from the trenches 71. Step 102 in the flow diagram shown in FIG. 1 is exemplified by the structure shown in FIG. 18.

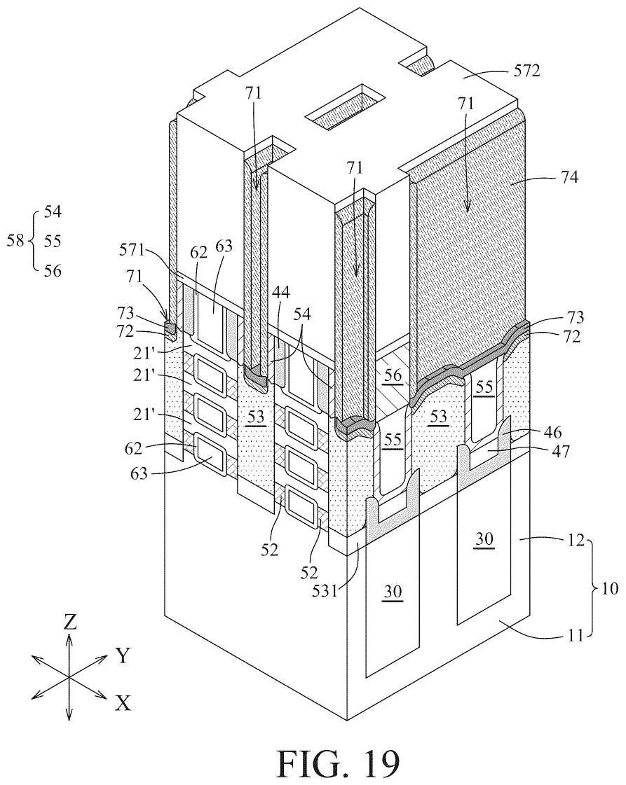

Referring to FIG. 19, contact spacers 74 are formed respectively along the patterned dielectric portions 58 in the trenches 71.

Spacer material layers for forming the contact spacers 74 are first formed in the trenches 71 on both the sidewalls (i.e., along the patterned dielectric portions 58 e.g., the CESLs 54 and/or the dielectric masks 56) and bottoms (i.e., on the cap features 73) thereof. In some embodiments, the spacer material layers are formed using any suitable deposition processes followed by removing an excess material on the patterned second mask layer 572 using any suitable processes (e.g., CMP). Afterwards, any suitable etching processes (e.g., a directional etching process such as a dry etching process directed to the bottoms of the trenches 71) may be adopted to remove bottom parts of the spacer material layers. The remaining sidewall parts of the spacer material layers serve as the contact spacers 74, and the cap features 73 are exposed from the contact spacers 74. In some embodiments, the spacer material layers may include or may be made of a dielectric material, such as silicon nitride, silicon oxynitride, silicon carbonitride, or other nitride-based dielectric materials, but is not limited thereto. Other suitable materials and/or processes for forming the contact spacers 74 are within the contemplated scope of the present disclosure.

After forming the contact spacers 74, each of the cap features 73 is partially covered by a corresponding one of the contact spacers 74. Specifically, each of the cap features 73 has a bottom surface connected to a corresponding one of the silicide layers 72, and a top surface opposite to the corresponding silicide layer 72. The top surface has a central region and a peripheral region surrounding the central region. The corresponding contact spacer 74 is disposed on and along the peripheral region, and the central region is exposed from the corresponding contact spacer 74. In addition, the contact spacers 74 are each formed over first region(s) of corresponding one(s) of the silicide layers 72. The first regions of the silicide layers 72 are each covered by the peripheral region(s) of corresponding one(s) of the cap features 73; and second regions of the silicide layers 72 are each covered by the central region(s) of corresponding one(s) of the cap features 73. Step 103 in the flow diagram shown in FIG. 1 is exemplified by the structure shown in FIG. 19.

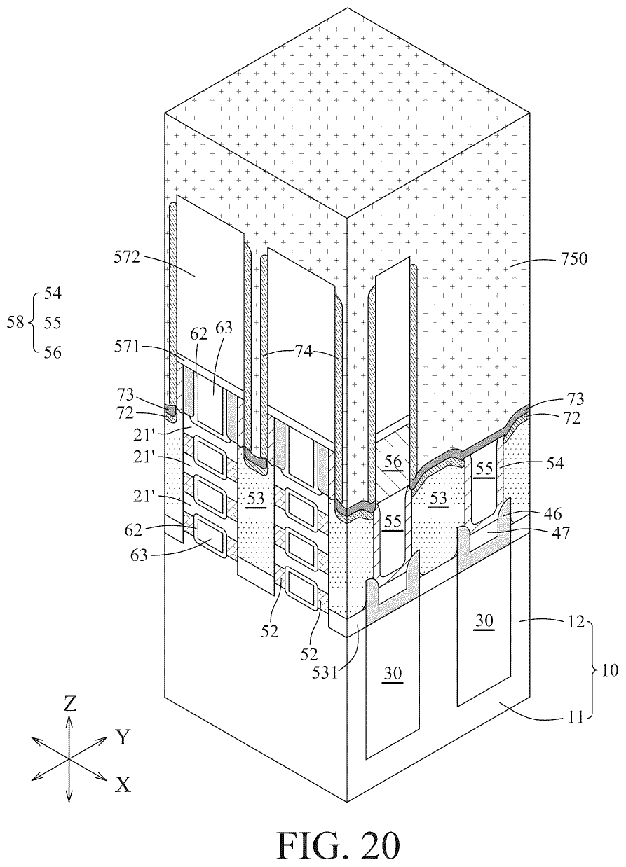

Referring to FIG. 20, a contact material layer 750 is formed over the structure shown in FIG. 19 to fill the trenches 71.

In some embodiments, the contact material layer 750 may include or may be made of a material similar to that of the cap features 73, such as tungsten (W), ruthenium, (Ru), molybdenum (Mo), or the like, or combinations thereof, but are not limited thereto. Other suitable materials for forming the contact material layer 750 are within the contemplated scope of the present disclosure. In some embodiments, the contact material layer 750 may have a material same as that of the cap features 73. In other embodiments, the contact material layer 750 may have a material different from that of the cap features 73.

Referring to FIG. 21, a planarization process (e.g., CMP, but is not limited thereto) is performed to remove an excess amount of the contact material layer 750 (see FIG. 20), so as to form conductive features 75 in the trenches 71 (see FIG. 19) on the central regions of the top surfaces of the cap features 73, respectively.

In the planarization process, the patterned first mask layer 571 and the patterned second mask layer 572 (see FIG. 20) are also removed, so that the gate structures (i.e., the gate dielectrics 62 and the gate electrodes 63), the gate spacers 44, the patterned dielectric portions 58 (e.g., the CESLs 54 and the dielectric masks 56), and the contact spacers 74 are exposed. The conductive features 75 obtained may have a top surface flush with a top surface of the gate structures. Step 104 in the flow diagram shown in FIG. 1 is exemplified by the structures shown in FIGS. 20 and 21. The semiconductor structure manufactured in accordance with some embodiments of the present disclosure is thereby obtained.

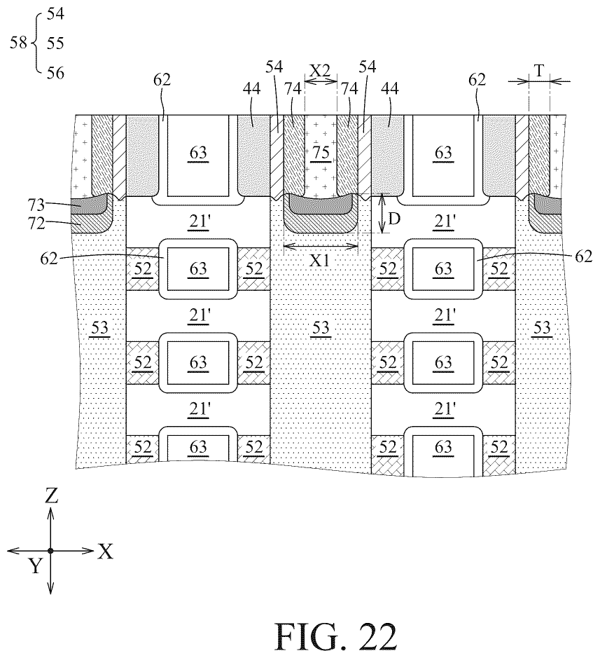

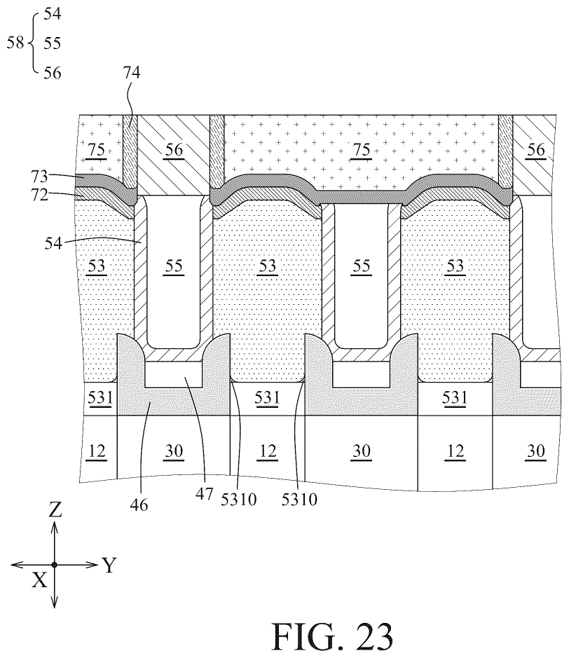

FIG. 22 is a schematic partial cross-sectional view of the structure shown in FIG. 21 taken along the X direction in accordance with some embodiments. FIG. 23 is another schematic partial cross-sectional view of the structure shown in FIG. 21 taken along the Y direction in accordance with some embodiments. Referring to FIG. 22, in certain embodiments, the silicide layers 72 have a depth (D, measured in the Z direction) ranging from about 10 nm to about 15 nm, but is not limited thereto. In some embodiments, the silicide layers 72 have a width (X1, measured in the X direction) ranging from about 8 nm to about 25 nm, but is not limited thereto. In some embodiments, the conductive features 75 may have a width (X2, measured in the X direction) ranging from about 6 nm to about 20 nm, but is not limited thereto. The width (X2) of the conductive features 75 is smaller than the width (X1) of the silicide layers 72. Referring to FIG. 23, in some embodiments, each of the source/drain features 53 may be spaced apart from a corresponding one of the interposing layers 531 and a corresponding one of the fin sidewalls 46 by a gap 5310.

It is noted that, in the present disclosure, the sequence of forming the silicide layers 72, the cap features 73, the contact spacers 74 and the conductive features 75 gives rise to the structural configuration of these elements, and is beneficial in certain aspects. Referring back to FIG. 1, in step 102, the silicide layers 72 (see FIG. 18) are first formed in the trenches 71, followed by forming the cap features 73 on the silicide layers 72. After completing step 102, each one of the silicide layers 72 is covered by a corresponding one of the cap features 73. The cap features 73 are configured to protect the silicide layers 72 underneath, and to provide a platform for the contact spacers 74 to be formed thereon. After completing step 103, the contact spacers 74 (see FIG. 19) are each formed on the peripheral region of a respective one of the cap features 73, leaving the central region of the respective cap feature 73 exposed. After completing step 104, the conductive features 75 (see FIG. 21) are each formed on the central region of a respective one of the cap features 73, and are each surrounded by a respective one of the contact spacers 74. Each of the conductive features 75, and the respective cap feature 73, cooperatively serve as a source/drain contact. That is, one source/drain contact includes one of the conductive features 75 that acts as a body portion of the source/drain contact, and the respective cap feature 73 that act as a base portion of the source/drain contact. It is noted that the body portion (i.e., the conductive feature 75) has a width smaller than a width of the base portion (i.e., the cap feature 73), along both the X direction (see FIG. 22) and the Y direction (see FIG. 23). The source/drain contact is partially surrounded by a respective one of the contact spacers 74. In other words, the sidewall of the body portion (i.e., the conductive feature 75), and the peripheral region of the top surface of the base portion (i.e., the cap feature 73) are connected to (or in contact with) the respective contact spacers 74. As shown in FIGS. 21 to 23, a plurality of source/drain contacts are formed over the source/drain features 53. The source/drain contacts are each electrically connected to corresponding one(s) of the source/drain features 53 through corresponding one(s) of the silicide layers 72.

One beneficial effect for the method described with reference to FIG. 1 is that by forming the silicide layers 72 first (and before forming the contact spacers 74), the silicide layers 72 may be formed with a greater width (measured in both the X direction and the Y direction), i.e., greater area, since the width is confined by mainly the patterned dielectric portions 58 (the CESLs 54 and/or the dielectric masks 56, see FIG. 18). Considering that the silicide layers 72 are formed with a greater area, a contact resistance between each of the source/drain contacts and a corresponding one of the source/drain features 53 though a corresponding one of the silicide layers 72 is reduced. In contrast, in some cases where the silicide layers are formed after forming the contact spacers, width of the silicide layers is confined by both the patterned dielectric portions and the contact spacers, which results in a smaller area of the silicide layers, and an undesirably increased contact resistance between the source/drain contacts and the source/drain features. In accordance with some embodiments of the present disclosure, by forming the silicide layers 72 first, a width (X1, see also FIG. 22) of the silicide layers 72 (measured in the X direction) may be increased by about 3 nm to about 5 nm (but is not limited thereto), in comparison with the case of forming the silicide layers after forming the contact spacers.

Another beneficial effect for the method described with reference to FIG. 1 is that by forming the contact spacers 74 after forming the silicide layers 72, the contact spacers 74 may be formed with a greater thickness (measured along the XY plane) away from the patterned dielectric portions 58 (the CESLs 54 and/or the dielectric masks 56) without affecting formation of the silicide layers 72. The thicker contact spacers 74 result in a greater distance, and thus a reduced capacitance, between each of the conductive features 75 and the gate electrode 63 of a corresponding adjacent one of the gate structures. In contrast, in some cases, where the contact spacers are formed before forming the silicide layers, in order to ensure sufficient space (in the trenches) for thoroughly removing the unreacted parts of the first metallic material layers during formation of the silicide layers, the contact spacers are formed with a relatively small thickness so as to allow a greater window for formation of the silicide layers. The thin contact spacers do not merit reduction in the capacitance between the conductive features and the gate electrodes. In accordance with some embodiments of the present disclosure, by forming the contact spacers 74 after forming the silicide layers 72, the thickness of the contact spacers 74 (or the distance between each of the conductive features 75 and the gate electrode 63 of the corresponding adjacent gate structure) may be increased by about 1 nm to about 2 nm (but is not limited thereto), in comparison with the case of forming the contact spacers before forming the silicide layers.

In accordance with some embodiments of the present disclosure, the semiconductor structure illustrated in FIGS. 2 to 23 have a gate-all-around (GAA) architecture, but is not limited thereto. In other embodiments, the method described with reference to FIG. 1 may also be applied in manufacturing semiconductor structures with other architectures, such as a fin-type field effect transistor (finFET), complementary FET (cFET), forksheet FET, planar FET, or the like, but are not limited thereto. Other suitable applications and/or architecture are within the contemplated scope of the present disclosure.

The embodiments of the present disclosure have the following advantageous features. In the trenches 71 that are bordered by the patterned dielectric portions 58 (i.e., the CESLs 54 and the dielectric mask 56) and the source/drain features 53, the silicide layers 72 and the cap features 73 are sequentially formed on the source/drain features 53; the contact spacers 74 are then formed along the patterned dielectric portions 58; and finally the conductive features 75 are formed on the cap features 73 and surrounded by the contact spacers 74. The silicide layers 72 formed thereby may have a larger width and thus area, which is conducive in reducing contact resistance between the source/drain contacts (combination of the conductive features 75 and the cap features 73) and the source/drain features 53. In addition, the contact spacers 74 formed thereby may have a greater thickness, which is beneficial in reducing capacitance between the conductive features 75 and gate electrodes 63 of the adjacent gate structures. As such, the semiconductor structure may have improved working performance.

In accordance with some embodiments of the present disclosure, a method for manufacturing a semiconductor structure includes: forming a patterned structure having: a source/drain feature; a channel portion connected to the source/drain feature; a gate structure formed over the channel portion; and a patterned dielectric portion over the source/drain feature, the patterned dielectric portion having a trench that exposes the source/drain feature; forming a silicide layer over the exposed source/drain feature in the trench, the silicide layer having a curved profile and having an electrical conductivity higher than an electrical conductivity of the source/drain feature; forming a cap feature over the silicide layer in the trench; after forming the silicide layer and the cap feature, forming a contact spacer along the patterned dielectric portion in the trench, the cap feature being exposed from the contact spacer; and forming a conductive feature in the trench on the cap feature.

In accordance with some embodiments of the present disclosure, the conductive feature has a width smaller than a width of the cap feature.

In accordance with some embodiments of the present disclosure, the width of the conductive feature ranges from 6 nm to 20 nm.

In accordance with some embodiments of the present disclosure, the contact spacer is formed on a top surface of the cap feature opposite to the silicide layer.

In accordance with some embodiments of the present disclosure, the contact spacer partially covers the cap feature.

In accordance with some embodiments of the present disclosure, the cap feature includes a conductive material, the cap feature and the conductive feature being electrically conductive with each other.

In accordance with some embodiments of the present disclosure, the cap feature includes tungsten, titanium, ruthenium, molybdenum, copper, cobalt, aluminum, palladium, nickel, platinum, or combinations thereof.

In accordance with some embodiments of the present disclosure, in the patterned structure, the channel portion includes channel features that are spaced apart from each other in a vertical direction, and the gate structure is formed to surround each of the channel features.

In accordance with some embodiments of the present disclosure, the patterned dielectric portion is formed by: sequentially forming a contact etch stop layer and an interlayer dielectric over the source/drain feature, a material of the contact etch stop layer being different from a material of the interlayer dielectric; recessing an upper portion of the interlayer dielectric that is located above the source/drain feature, leaving a lower portion of the interlayer dielectric aside the source/drain feature; forming a dielectric mask over the source/drain feature to form a dielectric portion, the dielectric portion including the contact etch stop layer, the recessed interlayer dielectric and the dielectric mask, a material of the dielectric mask being different from a material of the interlayer dielectric; and patterning the dielectric portion to obtain the trench and the patterned dielectric portion.

In accordance with some embodiments of the present disclosure, a method for manufacturing a semiconductor structure includes: forming a patterned structure having a source/drain feature, a channel portion located adjacent to the source/drain feature, and a gate structure formed over the channel portion; forming a silicide layer over the source/drain feature; forming a contact spacer over a first region of the silicide layer; and forming a conductive feature over a second region of the silicide layer, the second region of the silicide layer being different from the first region.

In accordance with some embodiments of the present disclosure, the silicide layer, the contact spacer and the conductive feature are sequentially formed.

In accordance with some embodiments of the present disclosure, the conductive feature is surrounded by the contact spacer.

In accordance with some embodiments of the present disclosure, the patterned structure further includes a patterned dielectric portion disposed over and exposing the source/drain feature, the contact spacer being formed on and along the patterned dielectric portion.

In accordance with some embodiments of the present disclosure, the conductive feature is spaced apart from the gate structure by the contact spacer and the patterned dielectric portion.

In accordance with some embodiments of the present disclosure, the method further includes forming a cap feature over the silicide layer prior to forming the contact spacer, a top surface of the cap feature opposite to the silicide layer having a central region and a peripheral region surrounding the central region, the contact spacer being formed on and along the peripheral region of the top surface of the cap feature, the central region of the top surface of the cap feature being exposed from the contact spacer, the conductive feature being formed on the central region of the top surface of the cap feature.

In accordance with some embodiments of the present disclosure, a width of the conductive feature is smaller than a width of the cap feature.

In accordance with some embodiments of the present disclosure, the silicide layer has a width ranging from 8 nm to 25 nm.

In accordance with some embodiments of the present disclosure, the width of the silicide layer is greater than a width of the conductive feature.

In accordance with some embodiments of the present disclosure, a semiconductor structure includes an active region, a channel portion disposed on the active region, a gate structure, a source/drain feature, a silicide layer, a cap feature, and a conductive feature. The active region extends lengthwise along a first direction. The gate structure is disposed over the channel portion and extends lengthwise along a second direction different from the first direction. The source/drain feature is disposed on the active region and is connected to the channel portion. The silicide layer, the cap feature, and the conductive feature are sequentially disposed on the source/drain feature. A width of the conductive feature is smaller than a width of the cap feature along both the first direction and the second direction.

In accordance with some embodiments of the present disclosure, a top surface of the cap feature opposite to the silicide layer has a central region and a peripheral region surrounding the central region. The conductive feature is disposed on the central region. The semiconductor structure further includes a contact spacer that is disposed on and along the peripheral region, and that surrounds the conductive feature.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a patterned structure having:
a source/drain feature;
a channel portion connected to the source/drain feature;
a gate structure formed over the channel portion; and
a patterned dielectric portion over the source/drain feature, the patterned dielectric portion having a trench that exposes the source/drain feature;
forming a silicide layer over the exposed source/drain feature in the trench, the silicide layer having a curved profile and having an electrical conductivity higher than an electrical conductivity of the source/drain feature;
forming a cap feature over the silicide layer in the trench;
after forming the silicide layer and the cap feature, forming a contact spacer along the patterned dielectric portion in the trench, the cap feature being exposed from the contact spacer; and
forming a conductive feature in the trench on the cap feature.

2. The method of claim 1, wherein the conductive feature has a width smaller than a width of the cap feature.

3. The method of claim 2, wherein the width of the conductive feature ranges from 6 nm to 20 nm.

4. The method of claim 1, wherein the contact spacer is formed on a top surface of the cap feature opposite to the silicide layer.

5. The method of claim 1, wherein the contact spacer partially covers the cap feature.

6. The method of claim 1, wherein the cap feature includes a conductive material, the cap feature and the conductive feature being electrically conductive with each other.

7. The method of claim 1, wherein the cap feature includes tungsten, titanium, ruthenium, molybdenum, copper, cobalt, aluminum, palladium, nickel, platinum, or combinations thereof.

8. The method of claim 1, wherein in the patterned structure,
the channel portion includes channel features that are spaced apart from each other in a vertical direction, and
the gate structure is formed to surround each of the channel features.

9. The method of claim 1, wherein the patterned dielectric portion is formed by:
sequentially forming a contact etch stop layer and an interlayer dielectric over the source/drain feature, a material of the contact etch stop layer being different from a material of the interlayer dielectric;
recessing an upper portion of the interlayer dielectric that is located above the source/drain feature, leaving a lower portion of the interlayer dielectric aside the source/drain feature;
forming a dielectric mask over the source/drain feature to form a dielectric portion, the dielectric portion including the contact etch stop layer, the recessed interlayer dielectric and the dielectric mask, a material of the dielectric mask being different from a material of the interlayer dielectric; and
patterning the dielectric portion to obtain the trench and the patterned dielectric portion.

10. A method for manufacturing a semiconductor structure, comprising:
forming a patterned structure having
a source/drain feature,
a channel portion located adjacent to the source/drain feature, and
a gate structure formed over the channel portion;
forming a silicide layer over the source/drain feature;
forming a contact spacer over a first region of the silicide layer; and
forming a conductive feature over a second region of the silicide layer, the second region of the silicide layer being different from the first region.

11. The method of claim 10, wherein the silicide layer, the contact spacer and the conductive feature are sequentially formed.

12. The method of claim 10, wherein the conductive feature is surrounded by the contact spacer.

13. The method of claim 10, wherein the patterned structure further includes a patterned dielectric portion disposed over and exposing the source/drain feature, the contact spacer being formed on and along the patterned dielectric portion.

14. The method of claim 13, wherein the conductive feature is spaced apart from the gate structure by the contact spacer and the patterned dielectric portion.

15. The method of claim 10, further comprising forming a cap feature over the silicide layer prior to forming the contact spacer, a top surface of the cap feature opposite to the silicide layer having a central region and a peripheral region surrounding the central region, the contact spacer being formed on and along the peripheral region of the top surface of the cap feature, the central region of the top surface of the cap feature being exposed from the contact spacer, the conductive feature being formed on the central region of the top surface of the cap feature.

16. The method of claim 15, wherein a width of the conductive feature is smaller than a width of the cap feature.

17. The method of claim 10, wherein the silicide layer has a width ranging from 8 nm to 25 nm.

18. The method of claim 17, wherein the width of the silicide layer is greater than a width of the conductive feature.

19. A semiconductor structure, comprising:
an active region extending lengthwise along a first direction;
a channel portion disposed on the active region;
a gate structure disposed over the channel portion and extending lengthwise along a second direction different from the first direction;
a source/drain feature disposed on the active region connected to the channel portion; and
a silicide layer, a cap feature, and a conductive feature sequentially disposed on the source/drain feature,
a width of the conductive feature being smaller than a width of the cap feature along both the first direction and the second direction.

20. The semiconductor structure of claim 19,
wherein a top surface of the cap feature opposite to the silicide layer has a central region and a peripheral region surrounding the central region, the conductive feature being disposed on the central region,
the semiconductor structure further comprising a contact spacer that is disposed on and along the peripheral region, and that surrounds the conductive feature.
